(19) United States
(12) Patent Application Publication
(10) Pub. No.: US 2008/0185285 A1
(43) Pub. Date: Aug. 7, 2008

(54) DESIGN SUPPORTING METHOD, SYSTEM, AND PROGRAM OF MAGNETRON SPUTTERING APPARATUS

(75) Inventors: Atsushi Furuya, Kawasaki (JP); Akihiko Fujisaki, Kawasaki (JP); Tetsuyuki Kubota, Kawasaki (JP)

Correspondence Address: STAAS & HALSEY LLP, SUITE 700, 1201 NEW YORK AVENUE, N.W., WASHINGTON, DC, 20005, US

(73) Assignee: Fujitsu Limited, Kawasaki (JP)

(21) Appl. No.: 11/960,905

(22) Filed: Dec. 20, 2007

(30) Foreign Application Priority Data
Feb. 5, 2007 (JP) 2007-025258

(51) Int. Cl. C23C 14/00

(52) U.S. Cl. 204/192.12; 204/298.16

(57) ABSTRACT

A static magnetic field structure data is read, a cross section which is parallel with the target surface and in which plasma is generated is specified at an arbitrary position, and an erosion center line segment having an endless shape which goes through the center of a region in which the magnetic field vertical to the plane of the specified cross section is zero is calculated. The static erosion rate distribution in the specified cross section of the magnetic field structure data is calculated based on the erosion rate of the erosion center line segment, the rotational erosion rate distribution caused along with rotation of the magnet is calculated, and the film formation rate distribution on the objective material is calculated by using the rotational erosion rate distribution.

This application is a priority based on prior application No. JP 2007-025258, filed Feb. 5, 2007, in Japan.

### BACKGROUND OF THE INVENTION

1. Field of the Invention

The present invention relates to a design supporting method, system, and program of magnetron sputtering which cause ion atoms, which are generated from plasma confined by a magnetic field formed in a surface side of a target, to collide with the target, thereby carrying out sputtering and forming a thin film on a wafer and particularly relates to a design supporting method, system, and program of magnetron sputtering which predicts the erosion distribution (removed amount distribution) of the target and the film formation distribution on the wafer in sputtering by simulation.

2. Description of the Related Arts

Conventionally, magnetron sputtering apparatus has been used in manufacturing of semiconductors, MEMS (Micro Electro Mechanical System), magnetic devices, etc. Magnetron sputtering apparatus is a manufacturing system in which plasma is confined by making a magnetic field by a permanent magnet or the like in the vicinity of a target serving as a film formation material, and ion atoms generated from the plasma are caused to collide with the target at a high speed while rotating the permanent magnet, thereby carrying out sputtering and forming a thin film on an intended wafer. In the magnetron sputtering, the film thickness of the film formed on the wafer surface is required to be uniform, and, at the same time, the erosion distribution (removed amount distribution) is required to be uniform so that the number of times of replacement of the target is small. In the magnetron sputtering, since the electrons emitted from the target have the nature that they wind around magnetic force lines, a permanent magnet is disposed in the back surface side of the target, thereby generating a magnetic field on the target surface and confining plasma. In this case, the magnetic field distribution is changed depending on the configuration of the permanent magnet, and the erosion distribution and the film formation distribution are changed. The magnetic field generated on the target surface is also dependent on the magnetic permeability of the target. Therefore, in order to carry out configuration designing of the permanent magnet that obtains optimal film formation distribution and erosion distribution, highly precise prediction by simulation is needed. The film formation distribution and erosion distribution in the magnetron sputtering depend on the state of plasma formed in the magnetic field on the target surface and the material property of the target. Therefore, in order to precisely predict the physical phenomenon of the erosion distribution of the target, three processes of (1) secondary electron emission process, (2) plasma state in the magnetic field, and (3) collision process of accelerated ions have to be analyzed. In JP06-280010, in order to calculate these physical phenomena, the electric field structure formed by the plasma is supposed, and the tracks of charged particles are calculated in accordance with the Newton's equation of motion. The PIC (Particle in Cell) method which also obtains the plasma density and electric field structure by self-consistent calculations is also present as a conventional method.

Meanwhile, when the equations of motion of charged particles are to be calculated, such conventional methods of predicting the erosion distribution of the target use the Monte Carlo method in which particles are generated by using random numbers, and calculations are carried out based on statistical average values based on massive particle tracks. However, several hundreds of particles have to be calculated per a minute unit area in order to precisely obtain the erosion distribution on the target surface, and massive calculation time is taken by the ability of a current computer. Moreover, measurement of collision probability of electrons and argon in plasma, the generation amount of secondary electrons, which are generated when argon ions collide with the target, the initial velocity, etc. is difficult, and there is a problem that tremendous time is required for adjustment of parameters in order to carry out precise calculations.

### SUMMARY OF THE INVENTION

According to the present invention to provide a design supporting method, system, and program of magnetron sputtering capable of calculating and predicting the erosion distribution of a target and the film formation distribution of a wafer in a short period of time merely by the magnetic field structure that confines plasma without calculating the motion of charged particles and a plasma fluid.

(Method)

The present invention provides a design supporting method of magnetron sputtering. The design supporting method of magnetron sputtering apparatus which forms a magnetic field in a surface side of a target, which is a film formation material, by a rotating magnet disposed in a back surface side of the target so as to confine plasma and causes ion atoms generated from the plasma to collide with the target at a high speed so as to carry out sputtering and form a thin film on an objective material such as a wafer includes:

a static magnetic field structure data reading step of reading a static magnetic field structure data generated in a stopped state of the magnet and storing the model in a memory unit;

a cross-section specifying step of specifying, at an arbitrary position of the static magnetic field structure data, a cross section which is parallel with the target surface and in which plasma is generated;

an erosion center line segment calculating step of calculating an erosion center line segment having an endless shape which goes through the center of a region in which a magnetic field vertical to a plane in the specified cross section of the static magnetic field structure data is zero;

a static erosion rate distribution calculating step of calculating static erosion rate distribution on a target surface based on an erosion rate of the erosion center line segment;

a rotational erosion rate distribution calculating step of calculating rotational erosion rate distribution by integration of the static erosion rate along with rotation of the magnet; and

a film formation rate distribution calculating step of calculating film formation rate distribution on the objective material by using the rotational erosion rate.

In the design supporting method of magnetron sputtering apparatus of the present invention, a static magnetic field analysis step of generating the static magnetic field structure data, which is read in the static magnetic field structure data reading step, by static magnetic field analysis may be further provided.

In that, in the cross section specifying step, an arbitrary cross section is specified with respect to the static magnetic field structure data based on a specifying operation of a user.

In the static magnetic field structure data, objective space is divided into minute cuboidal meshes, a magnetic field (Bx, By, Bz) three-dimensionally calculated based on material property and shapes of the magnet and target present in the objective space is disposed for each coordinate (X[Ix], Y[Iy], Z[Iz]) of a predetermined vertex of the cuboidal mesh.

In the erosion center line segment calculating step, when the specified cross section of the static magnetic field structure data cuts the cuboidal mesh, the vertical magnetic field of the cross section position is calculated by interpolation calculations of vertical magnetic fields set at two vertices positioned so as to sandwich the cut surface of the cuboidal mesh in a vertical direction.

In the erosion center line segment calculating step,

a line segment in which one side of the vertical magnetic field is a positive magnetic field and the other side is a negative magnetic field is extracted from the line segments between lattice points in the two-dimensional meshes constituting the specified cross section of the static magnetic field structure data; and,

for each extracted line segment, a position at which the vertical magnetic field on the line segment is zero is calculated by linear interpolation calculations of the positive magnetic field and the negative magnetic field, rearrangement is carried out so that the calculated vertical magnetic field zero positions are adjacent to each other, and coordinate data representing an erosion center line is generated.

In the erosion center line segment calculating step, in accordance with needs, a misaligned distance due to centrifugal force caused along rotational motion of plasma particles may be calculated and corrected based on curvature of the erosion center line segment.

In the static erosion rate distribution calculating step, the static erosion rate distribution is calculated based on a Gaussian function model or other distribution function models such as lorentz function.

In the static erosion rate distribution calculating step, an erosion rate and distribution width on an erosion center line segment set in advance are read, the distance from a lattice point of the two-dimensional meshes constituting the specified cross section of the static magnetic field structure data to the erosion center line segment is calculated, and the static erosion rate of the cell to which the lattice point belongs is calculated based on the Gaussian function model wherein the erosion rate, distribution width, and distance are used as calculation parameters.

In the static erosion rate distribution calculating step, as distances from the lattice point of the two-dimensional meshes to the erosion center line segment, the distances between the lattice point and all coordinate points constituting the static erosion center line are calculated, and a minimum distance among the calculated distances is selected.

In the rotational erosion distribution calculating step, the erosion rate at an arbitrary position of the two-dimensional mesh in the specified cross section is calculated by an interpolation calculation based on the erosion rates calculated in the static erosion rate calculating step of four lattice points of a cell including the arbitrary position, and the rotational erosion rate distribution is calculated by integration of the erosion rates of the lattice points of the two-dimensional meshes and the arbitrary position according to rotation of the magnet.

In the film formation rate distribution calculating step, the film formation rate distribution is calculated from the rotational erosion rate distribution and scattering angle dependency.

The present invention provides a design supporting system of magnetron sputtering apparatus. The present invention forms a magnetic field in a surface side of a target, which is a film formation material, by a rotating magnet disposed in a back surface side of the target so as to confine plasma and causes ion atoms generated from the plasma to collide with the target at a high speed so as to carry out sputtering and form a thin film on an objective material such as a wafer, and has:

a static magnetic field structure data reading unit which reads a static magnetic field structure data generated in a stopped state of the magnet and storing the model in a memory unit;

a cross-section specifying unit which specifies, at an arbitrary position of the static magnetic field structure data, a cross section which is parallel with the target surface and in which plasma is generated;

an erosion center line segment calculating unit which calculates an erosion center line segment having an endless shape which goes through the center of a region in which a magnetic field vertical to a plane in the specified cross section of the static magnetic field structure data is zero;

a static erosion rate distribution calculating unit which calculates static erosion rate distribution in the specified cross section of the static magnetic field structure data based on an erosion rate of the erosion center line segment;

a rotational erosion rate distribution calculating unit which calculates rotational erosion rate distribution by integration of the static erosion rate along with rotation of the magnet; and

a film formation rate distribution calculating unit which calculates film formation rate distribution on the objective material by using the rotational erosion rate.

(Program)

The present invention provides a program executed by a computer of the design supporting system of magnetron sputtering apparatus.

The program of the present invention causes a computer of a design supporting system of magnetron sputtering apparatus which forms a magnetic field in a surface side of a target, which is a film formation material, by a magnet, which is disposed in a back surface side of the target and rotates, so as to confine plasma and causes ion atoms generated from the plasma to collide with the target at a high speed so as to carry out sputtering and form a thin film on an objective material such as a wafer, to execute:

a static magnetic field structure data reading step of reading a static magnetic field structure data generated in a stopped state of the magnet and storing the model in a memory unit;

a cross-section specifying step of specifying, at an arbitrary position of the static magnetic field structure data, a cross section which is parallel with the target surface and in which plasma is generated;

an erosion center line segment calculating step of calculating an erosion center line segment having an endless shape which goes through the center of a region in which a magnetic field vertical to a plane in the specified cross section of the static magnetic field structure data is zero;

a static erosion rate distribution calculating step of calculating static erosion rate distribution in the specified cross section of the static magnetic field structure data based on an erosion rate of the erosion center line segment;

a rotational erosion rate distribution calculating step of calculating rotational erosion rate distribution by integration of the static erosion rate along with rotation of the magnet; and

a film formation rate distribution calculating step of calculating film formation rate distribution on the objective material by using the rotational erosion rate.

(Simulation Method)

The present invention provides a simulation method of magnetron sputtering. In the present invention, the simulation method of magnetron sputtering which forms a magnetic field in a surface side of a target, which is a film formation material, by a rotating magnet disposed in a back surface side of the target so as to confine plasma and causes ion atoms generated from the plasma to collide with the target at a high speed so as to carry out sputtering and form a thin film on an objective material such as a wafer, includes:

a static magnetic field structure data reading step of reading a static magnetic field structure data generated in a stopped state of the magnet and storing the model in a memory unit;

a cross-section specifying step of specifying, at an arbitrary position of the magnetic field structure data, a cross section which is parallel with the target surface and in which plasma is generated;

an erosion center line segment calculating step of calculating an erosion center line segment having an endless shape which goes through the center of a region in which a magnetic field vertical with respect to a plane in the specified cross section of the static magnetic field structure data is a static erosion rate distribution calculating step of calculating static erosion rate distribution in the specified cross section of the static magnetic field structure data based on an erosion rate of the erosion center line segment;

a rotational erosion rate distribution calculating step of calculating rotational erosion rate distribution by integration of the static erosion rate along with rotation of the magnet; and

a film formation rate distribution calculating step of calculating film formation rate distribution on the objective material by using the rotational erosion

(Simulation System)

The present invention provides a simulation system of magnetron sputtering. In the present invention, the simulation system of magnetron sputtering which forms a magnetic field in a surface side of a target, which is a film formation material, by a rotating magnet disposed in a back surface side of the target so as to confine plasma and causes ion atoms generated from the plasma to collide with the target at a high speed so as to carry out sputtering and form a thin film on an objective material such as a wafer, has:

a static magnetic field structure data reading unit which reads a static magnetic field structure data generated in a stopped state of the magnet and storing the model in a memory unit;

a cross-section specifying unit which specifies, at an arbitrary position of the magnetic field structure data, a cross section which is parallel with the target surface and in which plasma is generated;

an erosion center line segment calculating unit which calculates an erosion center line segment having an endless shape which goes through the center of a region in which a magnetic field vertical to a plane in the specified cross section of the static magnetic field structure data is zero;

a static erosion rate distribution calculating unit which calculates static erosion rate distribution in the specified cross section of the magnetic field structure data based on an erosion rate of the erosion center line segment;

a rotational erosion rate distribution calculating unit which calculates rotational erosion rate distribution by integration of the static erosion rate along with rotation of the magnet; and

a film formation rate distribution calculating unit which calculates film formation rate distribution on the objective material by using the rotational erosion rate.

According to the present invention, the erosion distribution and the film formation distribution is directly calculated from the static magnetic field structure data of magnetron sputtering apparatus; therefore, without calculating the plasma distribution and motion of charged particles in detail, change of the erosion distribution and the film formation distribution due to change of the magnet shape can be predicted in a short period of time. The erosion distribution and the film formation distribution can be calculated based on the static magnetic field structure data of magnetron sputtering apparatus; therefore, configuration of the permanent magnet by which a magnetic field of optimal process conditions can be predicted in a short period of time. Furthermore, although the Monte Carlo method which calculates generation, target collision, and film formation particle scattering of charged particles by using random numbers requires, for example several tens to hundreds of calculations per one cell serving as a unit area divided by a two-dimensional mesh since the distribution in the wafer plane is precisely calculated; in the calculations of the present invention, one cell requires merely one time of calculation, the calculation load of the computer is significantly reduced, the erosion distribution and film formation distribution can be efficiently predicted in a short period of time by normal calculation capacity that a personal computer has, and an appropriate designing operation of magnetron based on the prediction results and an adjustment operation of determining the magnet configuration can be realized. The above and other objects, features, and advantages of the present invention will become more apparent from the following detailed description with reference to the drawings.

### BRIEF DESCRIPTION OF THE DRAWINGS

FIG. 1 is a block diagram of a functional configuration showing an embodiment of a magnetron sputtering apparatus's design supporting system according to the present invention;

FIG. 2 is a block diagram of a hardware environment of a computer in which a program of the present invention is executed;

FIG. 3 is a flow chart showing a magnetron sputtering apparatus design supporting process according to the embodiment of FIG. 1;

FIG. 4 is a structure explanatory diagram of magnetron sputtering apparatus to which the present embodiment is applied;

FIG. 5 is an explanatory diagram of a static magnetic field structure data used in the present embodiment;

FIG. 6 is an explanatory diagram of interpolation calculation of vertical magnetic field of the specified cross section with respect to the static magnetic field structure;

FIG. 7 is an explanatory diagram of magnetic force line distribution and an erosion center line segment on a target surface;

FIG. 8 is an explanatory diagram of the erosion center line segment in the specified cross section of the static magnetic field structure data;

FIG. 9 is an explanatory diagram of calculation of coordinate positions of line segments between lattices at which vertical magnetic fields forming the erosion center line segment in two-dimensional mesh of the specified cross section are zero;

FIGS. 10A to 10C are explanatory diagrams of a process of detecting the distances between a cell lattice point and the erosion center line segment;

FIG. 11 is a flow chart of the process of detecting the distances between the cell lattice point and the erosion center line segment;

FIGS. 12A and 12B are explanatory diagrams of a process of obtaining rotational erosion rate distribution by rotating the static erosion rate distribution;

FIG. 13 is an explanatory diagram for calculating the erosion rate of an arbitrary position from the static erosion rates of cell lattice points; and

FIG. 14 is an explanatory diagram of a process of obtaining a film formation rate distribution of the wafer from the rotational erosion rate distribution of the target.

### DETAILED DESCRIPTION OF THE PREFERRED EMBODIMENTS

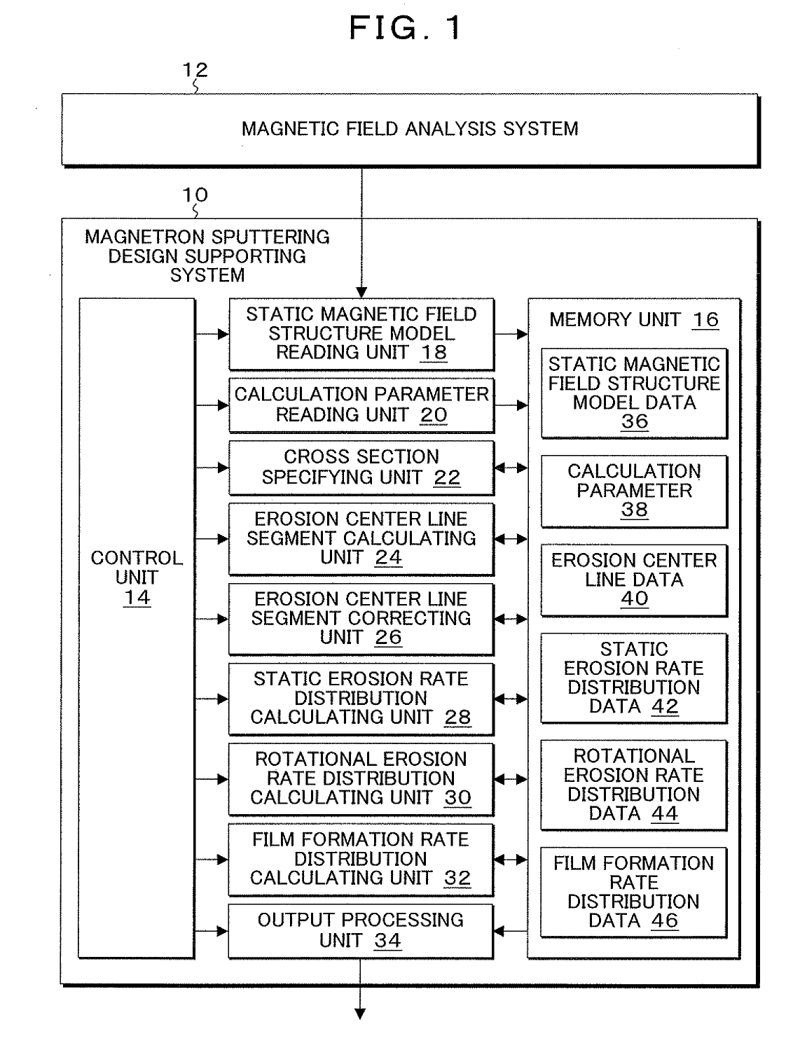

FIG. 1 is a block diagram of a functional configuration showing an embodiment of a magnetron sputtering apparatus's design supporting system according to the present invention. In FIG. 1, the magnetron sputtering apparatus's design supporting system 10 of the present embodiment is a function realized by executing a program by a computer. In the magnetron sputtering apparatus's design supporting system 10 of the present embodiment, a control unit 14 and a memory unit 16 are provided. Furthermore, for design support of magnetron sputtering apparatus, a static magnetic field structure data reading unit 18, a calculation parameter reading unit 20, a cross-section specifying unit 22, an erosion center line segment calculating unit 24, an erosion center line segment correcting unit 26, a static erosion rate distribution calculating unit 28, a rotational erosion rate distribution calculating unit 30, a film formation rate distribution calculating unit 32, and an output processing unit 34 are provided. In the memory unit 16, static magnetic field structure data 36 and calculation parameters 38 read upon processing initiation of the magnetron sputtering apparatus's design supporting system 10 and erosion center line data 40, static erosion rate distribution data 42, rotational erosion rate distribution data 44, and film formation rate distribution data 46 generated through execution of processing are stored. Furthermore, in the present embodiment, a magnetic field analysis system 12 is provided for the magnetron sputtering apparatus's design supporting system 10, so that the static magnetic field structure data data 36 generated by magnetic field analysis of magnetron sputtering apparatus by the magnetic field analysis system is read. The magnetic field analysis system 12 may be provided separately from the magnetron sputtering apparatus's design supporting system 10 of the present embodiment or may be included in the magnetron sputtering apparatus's design supporting system 10. As a matter of course, the processing function of the magnetic field analysis system 12 is also a function realized by executing a magnetic field analysis program by a computer. The static magnetic field structure data reading unit 18 provided in the magnetron sputtering apparatus's design supporting system 10 reads, for example, a static magnetic field structure data which is generated by the magnetic field analysis system 12 in a magnet-stopped state in magnetron sputtering apparatus serving as a design objective and stores it as the model data 36 in the memory unit 16. The calculation parameter reading unit 20 reads erosion rates on an erosion center line segment used by the static erosion rate distribution calculating unit 28 and the distribution width thereof and stores them as the calculation parameters 38 in the memory unit 16. With respect to a static magnetic field structure data, the cross-section specifying unit 22 specifies, at an arbitrary position therein, a cross section which is parallel with the target surface in magnetron sputtering apparatus and in which plasma is generated. In this cross-section specification, an arbitrary cross section position can be specified by specification by a user. The erosion center line segment calculating unit 24 calculates an endless-shaped, i.e., ring-like erosion center line segment which goes through the center of a region in which the vertical magnetic field in the specified cross section in the static magnetic field structure data is zero and stores the erosion center line data 40 in the memory unit 16. The erosion center line segment correcting unit 26 is selectively executed in accordance with needs and, based on the curvature of the erosion center line segment, calculates and corrects the misaligned distance of the erosion center line segment that is caused along with rotational motion of plasma particles in magnetron sputtering apparatus. Without carrying out the correction process by the erosion center line segment correcting unit 26, the erosion center line data 40 calculated by the erosion center line segment calculating unit 24 may be used without modification. The static erosion rate distribution calculating unit 28 calculates static erosion rate distribution in the specified cross section of the static magnetic field structure data based on the erosion rates of the erosion center line segment. In the present embodiment, as a calculation method of the static erosion distribution, calculations of static erosion rate distribution based on a Gaussian function model are taken as an example. Note that in the calculation of the static erosion rate distribution, for example, a Lorenz function model can be used other than the Gaussian function model. In the calculations of the static erosion rate distribution using a Gaussian function model, the erosion rates and distribution width on the erosion center line, which are the calculation parameters 38 read by the calculation parameter reading unit 20, are used. The rotational erosion rate distribution calculating unit 30 calculates rotational erosion rate distribution, which is caused along with rotation of a permanent magnet in magnetron sputtering apparatus, by using the static erosion rate distribution data 42 and stores it as the rotational erosion rate distribution data 44 in the memory unit 16. More specifically, the rotational erosion rate distribution can be calculated by subjecting the static erosion rate distribution to integration in accordance with rotational motion of the permanent magnet in magnetron sputtering apparatus. The film formation rate distribution calculating unit 32 calculates the film formation rate distribution on the wafer by using the rotational erosion rate distribution data 44 and stores it as the film formation rate distribution data 46 in the memory unit 16. In the calculation process by the film formation rate distribution calculating unit 32, the film formation rate distribution on the wafer can be calculated from the rotational erosion rate distribution and scattering angle dependency. The output processing unit 34 reads the rotational erosion rate distribution data 44 and/or the film formation rate distribution data 46 of the memory unit 16 calculated by the rotational erosion rate distribution calculating unit 30 and the film formation rate distribution calculating unit 32 and outputs it as processing results of a magnetron sputtering apparatus's design supporting process, i.e., rotational erosion rate distribution and film formation rate distribution predicted by calculation processing so as to utilize them to evaluate whether the disposed position and shape of the permanent magnet in the magnetron sputtering apparatus serving as the design objective are appropriate or not. The output results by the output processing unit 34 may be displayed as numerical data or may be displayed in a design model of magnetron sputtering apparatus in combination with image data.

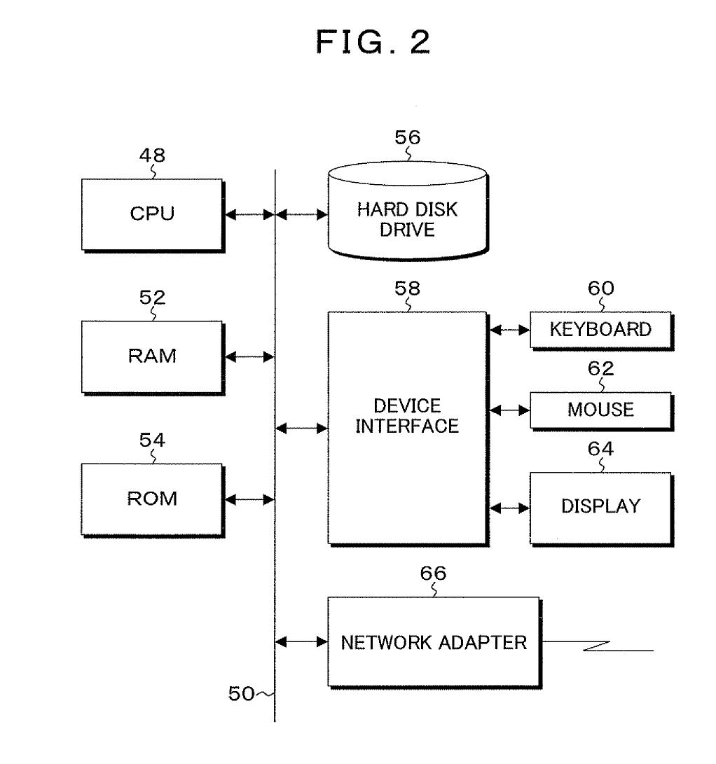

FIG. 2 is a block diagram of a hardware environment of a computer which executes a program of the magnetron sputtering apparatus's design supporting process according to the present invention. In FIG. 2, with respect to a bus 50 of a CPU 48, a RAM 52; a ROM 54; a hard disk drive 56; a device interface 58 connecting a keyboard 60, a mouse 62, and a display 64; and a network adapter 66 are provided. In the hard disk drive 56, the program for magnetron sputtering apparatus's design support in the present embodiment is stored. When the computer is started up, an OS is read and allocated from the hard disk drive 56 to the RAM 52 by a boot-up process by BIOS, and the program for magnetron sputtering apparatus's design support of the present embodiment, which is an application program of the hard disk drive 56 using the OS, is read and allocated to the RAM 52 and executed by the CPU 48, thereby realizing the functions shown in the magnetron sputtering apparatus's design supporting system 10 of FIG. 1.

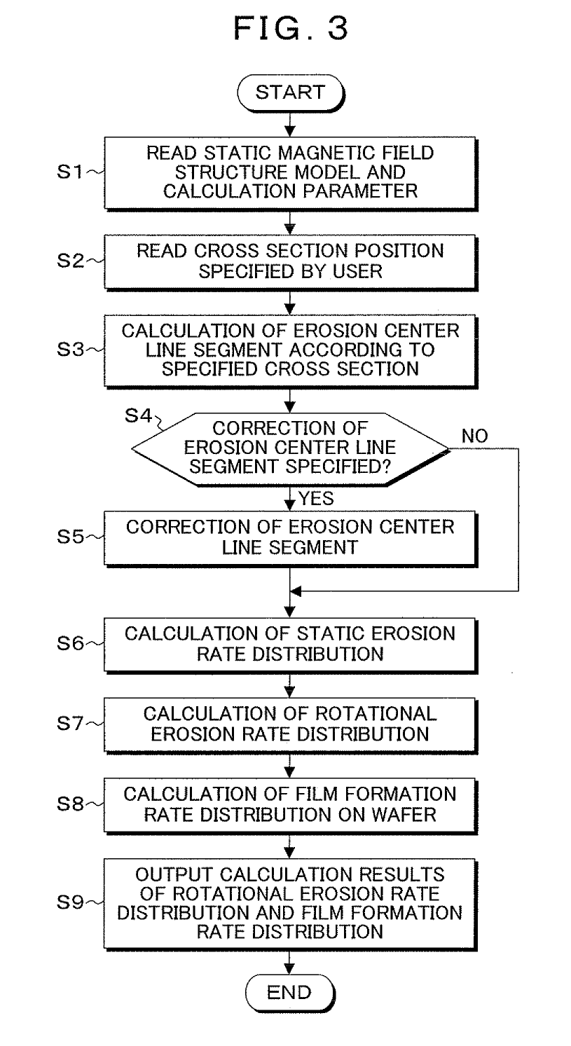

FIG. 3 is a flow chart showing the magnetron sputtering apparatus's design supporting process according to the present embodiment of FIG. 1, and the contents of the flow chart represent the contents of the program for the magnetron sputtering apparatus's design supporting process in the present embodiment. In FIG. 3, in the magnetron sputtering apparatus's design supporting process of the present embodiment, first of all, in step S1, the static magnetic field structure data reading unit 18 reads a static magnetic field structure data of magnetron sputtering apparatus generated, for example, by the magnetic field analysis system 12, at the same time, the calculation parameter reading unit 20 reads calculation parameters used in calculations of static erosion rate distribution, and they are stored in the memory unit 16. Subsequently, in step S2, the cross-section specifying unit 22 reads a cross-section position serving as a plasma generation position with respect to the static magnetic field structure data that is specified by a user at the moment. Next, in step S3, an erosion center line segment which goes through the center of the region in which the vertical magnetic field is zero in the specified cross section with respect to the static magnetic field structure data is derived by calculation by the erosion center line segment calculating unit 24. Subsequently, in step S4, whether correction of the erosion center line segment is specified or not is checked. If the correction is specified, the process proceeds to step S5 in which the erosion center line segment correcting unit 26 calculates, based on the curvature of the erosion center line segment, the misaligned distance caused by the eccentric force generated along with rotational motion of plasma particles, thereby correcting the erosion center line segment. If correction of the erosion center line segment is not specified in step S4, the process skips step S5 and proceeds to step S6. In step S6, the static erosion rate distribution calculating unit 28 calculates static erosion rate distribution based on a Gaussian function model in the present embodiment. Subsequently, in step S7, the rotational erosion rate distribution calculating unit 30 calculates rotational erosion rate distribution by performing integration involving rotation of the magnet based on statistic erosion rates. Subsequently, in step S8, the film formation rate distribution calculating unit 32 calculates film formation rate distribution on the wafer based on the rotational erosion rate distribution. Finally, in step S9, the output processing unit 34 outputs the calculation results of the rotational erosion rate distribution calculated in step S7 and the film formation rate distribution calculated in step S8. Subsequently, the magnetron sputtering apparatus's design supporting system 10 of FIG. 1 and the processing functions for the magnetron sputtering apparatus's design process shown in the flow chart of FIG. 3 will be described in detail.

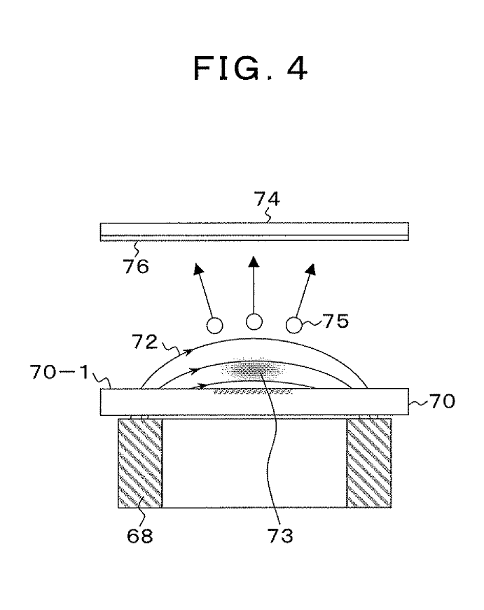

FIG. 4 is an explanatory diagram showing a conceptual structure of magnetron sputtering apparatus for which the present embodiment is carried out. In FIG. 4, in the magnetron sputtering apparatus, a permanent magnet 68 is disposed in the back surface side of a target 70, which is a film formation material, thereby generating a magnetic field by magnetic force lines 72 on a target surface 70-1 and confining plasma 73. The plasma 73 is formed at a position at which the magnetic force lines 72 are parallel with the target surface 70-1. This depends on the fact that the plasma 73 has a characteristic that the plasma moves so as to wind around the magnetic force lines 72 and a characteristic that the density of the plasma is high in the area in which the magnetic field is weak. Therefore, the erosion rates on the target surface 70-1 have a peak at a position at which the vertical magnetic field component is 0 where the density of the plasma 73 is high. Therefore, in the present embodiment, the erosion center line segment at which the vertical magnetic field formed by the magnetic force lines 72 is zero is extracted. In order to extract the erosion center line segment, in the present embodiment, a static magnetic field structure data is generated by magnetic field analysis and read for objective magnetron sputtering.

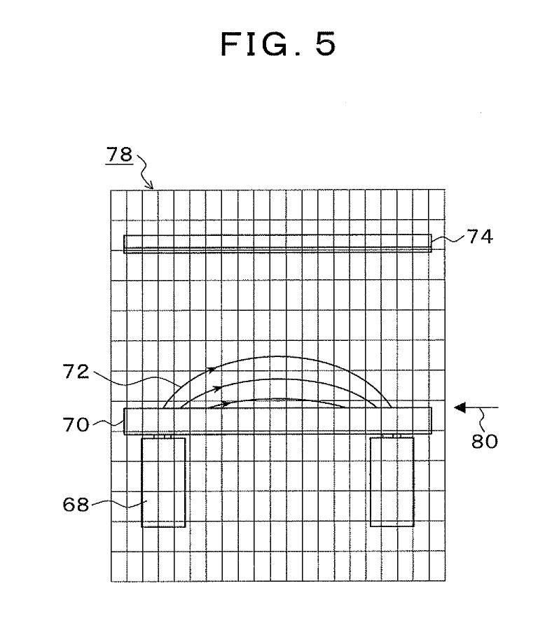

FIG. 5 is an explanatory diagram of a static magnetic field structure data used in the present embodiment. In FIG. 5, in the static magnetic field structure data 78, objective space is divided into cuboidal meshes, and three-dimensionally calculated static magnetic field data is read for each cuboidal mesh based on the material property and shape of the permanent magnet 68 and the target 70 in the magnetron sputtering apparatus serving as a calculation objective. The magnetic field elements and coordinates of each cuboidal mesh constituting the static magnetic field structure data 78 can be expressed as the following.

### Magnetic Field Elements:

### Bx [Ix][Iy][Iz], By [Ix][Iy][Iz], Bz [Ix][Iy][Iz]

### Coordinate:

### X [Ix], Y [Iy], Z [Iz]

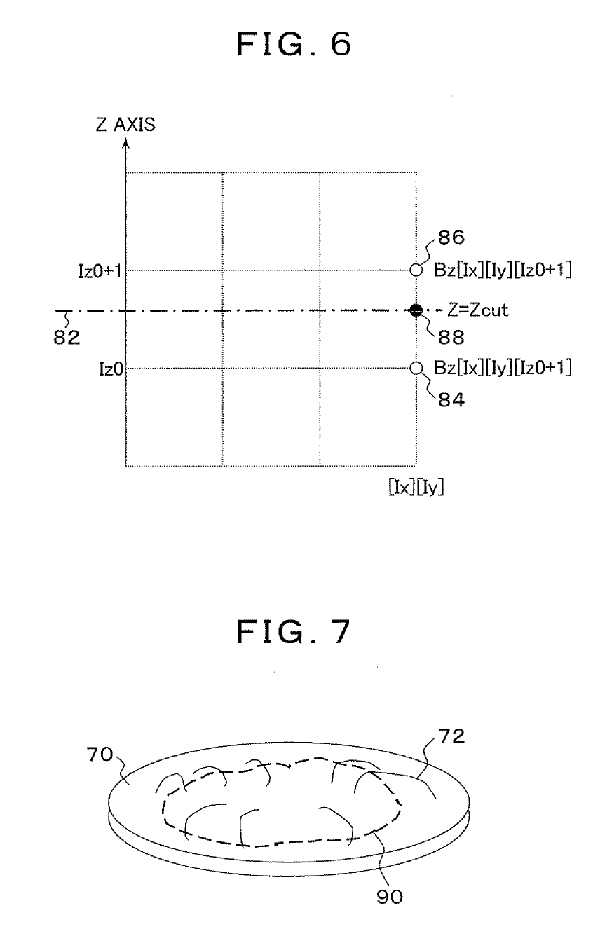

Herein, X [Ix] represents an Ix-th X coordinate, Y [Iy] represents an Iy-th Y coordinate, and Z [Iz] represents an Iz-th z coordinate. The magnetic field vector at the position specified by above described Ix, Iy, and Iz is (Bx, By, Bz), wherein a vertical magnetic field component is expressed by. Bz since a Z axis is taken in the direction perpendicular to the target surface 70-1. When the objective space as shown in FIG. 5 is divided by cuboidal meshes, and static magnetic field structure data composed of coordinate positions and magnetic field elements are read and stored in the memory unit 16 for each cuboidal mesh, with respect to, for example, a cross section specified position 80 of FIG. 5 with respect to the static magnetic field structure data 78 specified by the user at the point, an erosion center line segment which goes through the cells at which the vertical magnetic field according to the erosion center line segment calculating unit 24 is 0 is calculated by magnetic field analysis of two-dimensional meshes in the specified cross section. In the calculation of the erosion center line segment, vertical magnetic field components of cell lattice points of two-dimensional meshes constituting the specified cross section according to the cross section specified position 80 in the static magnetic field structure data 78 shown in FIG. 5 are required to be obtained. When the cross section specified position 80 is the boundary part of the vertical meshes in the static magnetic field structure data 78, the vertical magnetic field Bz of the static magnetic field structure data stored in the memory unit 16 can be used without modification; however, as is focused and shown in FIG. 6, when a specified cross section 82 is set at a position cutting the cells in the model vertical cross section, the vertical magnetic field in the specified cross section 82 has to be obtained by interpolation calculations.

In FIG. 6, for example, a vertical magnetic field Bz_cut of an interpolation point 88 between cell lattice points 84 and 86 is obtained by interpolation calculations by the below expressions when Z=Zcut.

$$\begin{matrix}\text{[Expressions 1]} & \\ Bz\_cut [ Ix ] [ Iy ] = ( 1 - Δ z ) \cdot Bz [ Ix ] [ Iz 0 ] + Δ z \cdot Bz [ Ix ] [ Iy ] [ Iz 0 + 1 ] & ( 1 ) \\ Δ z = \frac{Zcut - Z [ Iz 0 ]}{Z [ Iz 0 + 1 ] - Z [ Iz 0 ]} & ( 2 )\end{matrix}$$

Specifically, the ratio ΔZ of the distance to the interpolation point 88 with respect to the line segment from the lattice point 84 to the lattice point 86 is obtained by the expression (2), and the vertical magnetic field Bz_cut of the interpolation point 88 is calculated by using the ratio ΔZ of the distance of the interpolation point 88 by the interpolation calculation according to the expression (1) using the vertical magnetic field components Bz of the lattice points 84 and 86. When the vertical magnetic field in such a specified cross section is obtained by interpolation calculations, the vertical magnetic field component of the specified cross section can be obtained even when an arbitrary cross section is specified with respect to the static magnetic field model which is discrete cuboidal meshes.

FIG. 7 is an explanatory diagram of the magnetic force line distribution and erosion center line segment on the target surface in the present embodiment. In FIG. 7, the magnetic force lines 72 are formed on the target surface by the permanent magnet disposed on the back surface of the target 70. In formation of such magnetic force lines 72, when the N pole of an approximately cylindrical permanent magnet positioned in the outer peripheral side is disposed on the back surface side of the target 70 and the S pole of a cylindrical permanent magnet is disposed at the center part, the magnetic force lines 72 in the direction from the outer periphery to the center can be formed. With respect to such magnetic force lines 72, at the position where the vertical magnetic field is zero, the density of plasma is high, erosion on the target surface has a peak, and the erosion center line segment 90 shown by a broken line representing the peak values thereof is present.

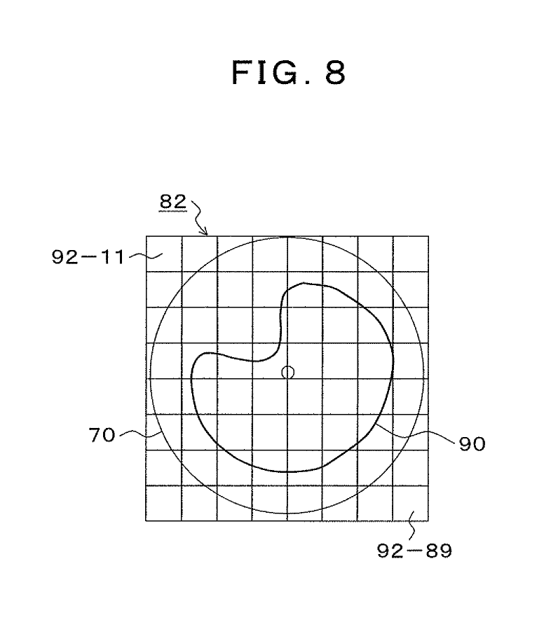

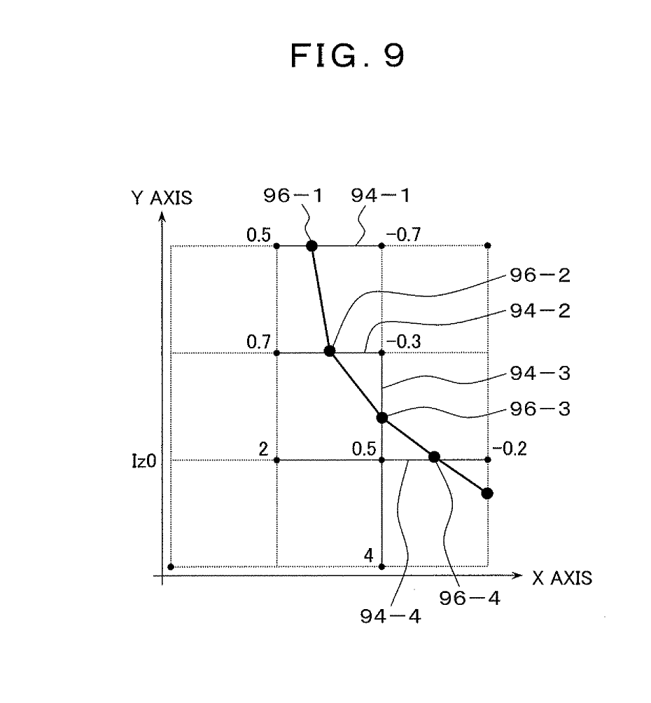

FIG. 8 is an explanatory diagram of the erosion center line segment in the specified cross section 82 obtained by specifying the cross section specified position 80 with respect to the static magnetic field structure data 78 of FIG. 5. In FIG. 8, the specified cross section 82 is two-dimensional meshes in the XY plane since the cuboidal meshes are cut by the specified cross section 82 which is orthogonal thereto in the perpendicular direction, and, in this example, it is divided into cells 92-11 to 92-89 which are eight in the lateral direction and nine in the vertical direction. Each of the cells 92-11 to 92-89 in the specified cross section 82 has data of the vertical magnetic field at each cell lattice point, and the erosion center line segment 90 can be generated by connecting the positions at which the vertical magnetic field is zero. In other words, according to the vertical magnetic field Bzcut_[Ix][Iy] obtained for the cells 92-11 to 92-89 in the two-dimensional meshes constituting the specified cross section 82, the contour line of Bz_cut=0 which is the erosion center is calculated as the erosion center line segment 90. Specifically, as shown in FIG. 9, the coordinate points representing the erosion center line segment are assumed to be on a line segment between the lattices of the two-dimensional meshes in the specified cross section, and the coordinates [Lx, Ly] at which Bz_cut=0 are calculated by linear interpolation with respect to the vertical magnetic field component Bz_cut. The line segment coordinates on the line segment between the lattices in the x-axis direction can be calculated by the below expressions.

$$\begin{matrix}\text{[Expressions 2]} & \\ Bz\_cut [ Ix ] [ Iy ] * Bz\_cut [ Ix + 1 ] [ Iy ] < 0 & ( 3 ) \\ Lx = \frac{\begin{matrix}Bz\_cut [ Ix + 1 ] [ Iy ] * X [ Ix ] - \\ Bz\_cut [ Ix ] [ Iy ] * X [ Ix + 1 ]\end{matrix}}{Bz\_cut [ Ix + 1 ] [ Iy ] - Bz\_cut [ Ix ] [ Iy ]} , Ly = Y [ Iy ] & ( 4 )\end{matrix}$$

Herein, the expression (3) extracts the line segment in which one of the values of the vertical magnetic field components Bz_cut of adjacent lattice points in FIG. 9 represents a positive magnetic field and the other one represents a negative magnetic field. The line segments extracted in FIG. 9 according to the condition expression of the expression (3) are line segments 94-1 to 94-4 in which one of lattice points is a positive magnetic field and the other one is a negative magnetic field. When the line segments that satisfy the condition expression of the expression (3) are extracted, the coordinates [Lx, Ly] of vertical magnetic field zero points 96-1 to 96-4 at which Bz_cut=0, in other words, the vertical magnetic field is zero can be calculated by interpolation calculation by weighting configuration of the values of the vertical magnetic fields of the both-side lattice points by the expression (4). There are a plurality of coordinates (Lx, Ly) representing the erosion center line segment calculated by the expressions (3) and (4); therefore, they are stored in the memory unit 16, which is a physical memory, as sequences Lx [N], Ly [N] of a size N, and they are rearranged so that the coordinates are adjacent to each other. When the erosion center line segment of the specified cross section 82 in the static magnetic field structure data 78 can be calculated in this manner, static erosion rate distribution is calculated by the static erosion rate distribution calculating unit 28 of FIG. 1.

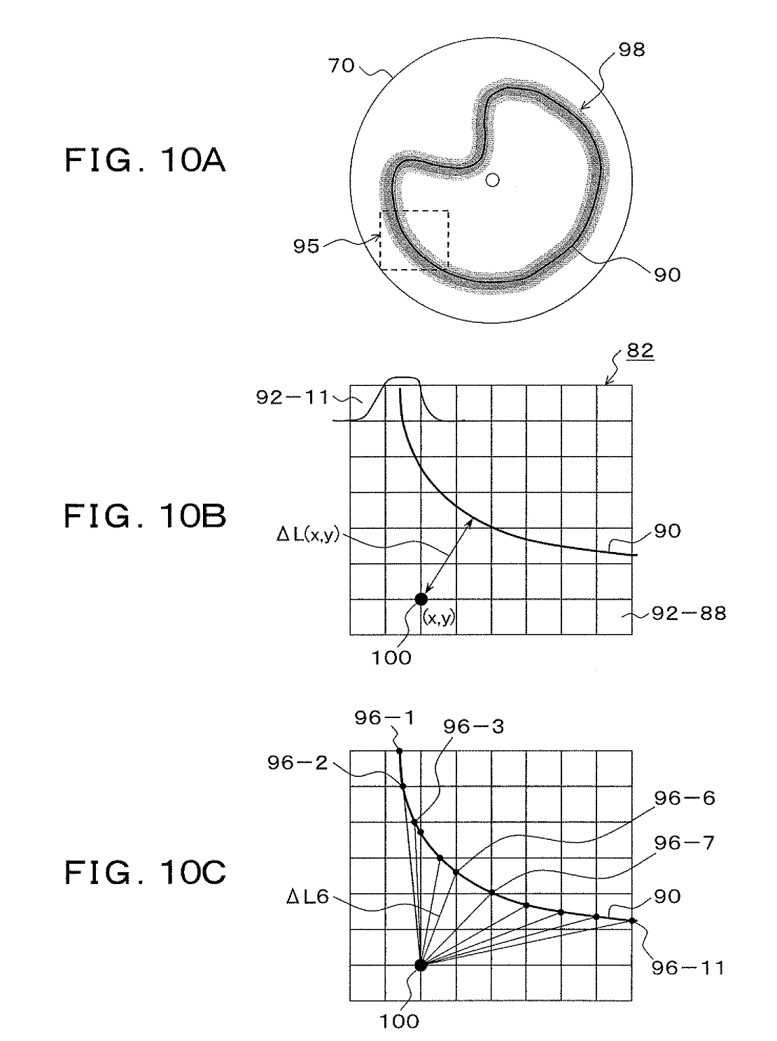

FIG. 10A shows the static erosion rate distribution with respect to the erosion center line segment. In FIG. 10A, static erosion rate distribution 98 in which, centered around the erosion center line segment 90 calculated for the specified cross section corresponding to the surface of the target 70, erosion is the largest at the position of the erosion center line segment 90, and the longer the distance therefrom, the more the erosion is reduced is calculated. In order to calculate the erosion rates at the target surface positions serving as the specified cross section, first of all, a distance ΔL from each of the cells disposed by the two-dimensional meshes to the erosion center line segment 90 has to be calculated.

FIG. 10B shows the distance from the lattice point of each cell in the specified cross section 82 and the erosion center line segment 90. The distance ΔL [x, y] of a lattice point 100 currently having coordinates [x, y] with respect to the erosion center line segment 90 calculated in the specified cross section 82 is calculated. In actual calculations, since the erosion center line segment 90 is discrete coordinate data shown by vertical magnetic field zero points 96-1 to 96-11 as shown in FIG. 10c, the distances between the vertical magnetic field zero points 96-1 to 96-11 and the lattice point 100 are calculated.

Specifically, all the distances between all the coordinate points constituting the erosion center line segment 90 and the lattice point 100 are calculated, and the minimum distance among the calculated distances, for example, a minimum distance ΔL6, i.e., the distance to the coordinate point 96-6 of the center line segment 90 in the case of FIG. 10C, is obtained as a distance for calculating the erosion rate.

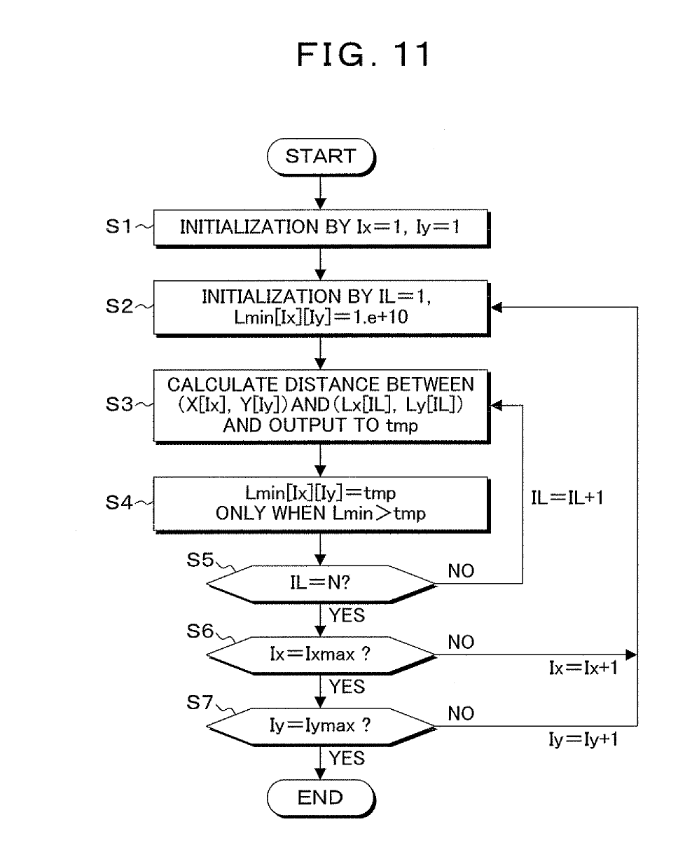

FIG. 11 is a flow chart of detection of the distances between the cell lattice point and the erosion center line segment in FIG. 10c. In FIG. 11, first of all, the coordinate [Ix, Iy] of the lattice point serving as a calculation objective is initialized in step S1, and a coordinate on the erosion center line segment is initialized in step S2. Subsequently, in step S3, the distance between the calculation objective lattice point and the first coordinate point of the erosion center line segment is calculated and output to a register tmp. Subsequently, in step S4, when the distance of the register tmp is smaller than a minimum distance min at the point, the value of the register at the point is stored in a minimum distance register min. Subsequently, in step S5, whether a coordinate value IL of the erosion center line segment has reached a maximum value N or not is determined. If it has not reached that, the calculation of the distance between the erosion center line segment and the coordinate point from step S3 is repeated. When the calculations of the distances with respect to all the coordinate points of the erosion center line segment are finished in step S5, a final distance is stored in the minimum distance register Lmin in step 54, and this is retained as the distance of the erosion distribution calculation.

Subsequently, in step S6, if Ix of the X coordinate of the lattice point serving as a calculation objective has not reached a maximum value Ixmax, it is increased by 1, and the process from step S2 is repeated. When it has reached Ixmax in step S6, the process proceeds to step S7 wherein the process from step S2 is repeated while increasing Iy which is a Y coordinate one at a time until Iy reaches a maximum value. As a result, the distances ΔL between, for example, all the lattice points of the two-dimensional meshes in the specified cross section 82 in FIG. 10C and the erosion center line segment 90 can be calculated. When the erosion center line data 40 is calculated by the erosion center line segment calculating unit 24 of FIG. 1 in this manner, a correction process by the erosion center line segment correcting unit 26 is carried out in accordance with needs. Regarding the correction of the erosion center line segment, when the motion velocity of the plasma particles in magnetron sputtering apparatus is fast, the phenomenon that the erosion center line segment is misaligned from the position at which the vertical magnetic field is zero due to the centrifugal force caused along with the rotary motion of the plasma particles is generated. Therefore, the misalignment due to the centrifugal force caused along with the rotary motion of the plasma particles has to be corrected for the erosion center line in accordance with needs. The centrifugal force caused along with the rotary motion of the plasma particles is proportional to the curvature of the erosion center line segment. Therefore, a curvature vector (KLx[N], KLy[N]) at a coordinate (Ly[N], Ly[N]) on the erosion center line segment can be calculated by the below expressions.

$$Ex [ N ] = \frac{Lx [ N + 1 ] - Lx [ N ]}{\sqrt{\begin{matrix}{( Lx [ N + 1 ] - Lx [ N ] )}^{2} + \\ {( Ly [ N + 1 ] - Ly [ N ] )}^{2}\end{matrix}}} \\ Ey [ N ] = \frac{Lx [ N + 1 ] - Lx [ N ]}{\sqrt{\begin{matrix}{( Lx [ N + 1 ] - Lx [ N ] )}^{2} + \\ {( Ly [ N + 1 ] - Ly [ N ] )}^{2}\end{matrix}}} \\ KLx [ N ] = \frac{Ex [ N ] - Ex [ N - 1 ]}{\sqrt{\begin{matrix}{( Lx [ N ] - Lx [ N - 1 ] )}^{2} + \\ {( Ly [ N ] - Ly [ N - 1 ] )}^{2}\end{matrix}}} \\ KLy [ N ] = \frac{Ey [ N ] - Ey [ N - 1 ]}{\sqrt{\begin{matrix}{( Lx [ N ] - Lx [ N - 1 ] )}^{2} + \\ {( Ly [ N ] - Ly [ N - 1 ] )}^{2}\end{matrix}}} \qquad [ Expressions 3 ]$$

When the curvature vector is calculated in this manner, the erosion center line segment can be corrected by the below expressions in proportion to the curvature. Herein, a coefficient shiftL may be either an arbitrarily set constant or an arbitrary function using at least either one of the vertical magnetic field at a lattice point in the vicinity and vertical magnetic field gradient obtained from the value thereof as a parameter.

### [Expressions 4]

Lx[N]=Lx[N]+shiftL·KLx[N], Lx[N]=Ly[N]+shiftL·KLy[N]

Next, details of a process by the static erosion rate distribution calculating unit 28 of FIG. 1 will be described. In the calculation process of a static erosion rate in the present embodiment, the calculation is carried out by using a Gaussian function model. In the Gaussian function model, the distance ΔL from each lattice point to the erosion center line segment L in the specified cross section obtained by the flow chart of FIG. 11, an erosion rate a [μm/S] on the erosion center line segment 90 which is a calculation parameter read by the calculation parameter reading unit 20 of FIG. 1, and β [mm] which is the distribution width thereof are used so as to calculate the erosion rate Er st (x, y) at the lattice point position (x, y) in the specified cross section which is a position on the target surface by the below expression.

$$\begin{matrix}[ Expression 5 ] & \\ Er\_st ( x , y ) = αexp ( - \frac{Δ L {( x , y )}^{2}}{{β}^{2}} ) & ( 5 )\end{matrix}$$

As the erosion rate Er_st [Ix][Iy] at the lattice point [Ix][Iy], the value obtained by the expression (5) is stored as the static erosion rate distribution data 42 in the memory unit 16 which is a physical memory. Note that the calculation model of the erosion rate is not limited to the Gaussian function of the expression (5), and, other than that, a model in which parameters α and β of the Lorenz function, the trigonometric function, or the Gaussian function are used as arbitrary functions of the magnetic field and the magnetic field gradient can be also applied. Next, the calculation process of the rotational erosion rate by the rotational erosion rate distribution calculating unit 30 of FIG. 1 will be described.

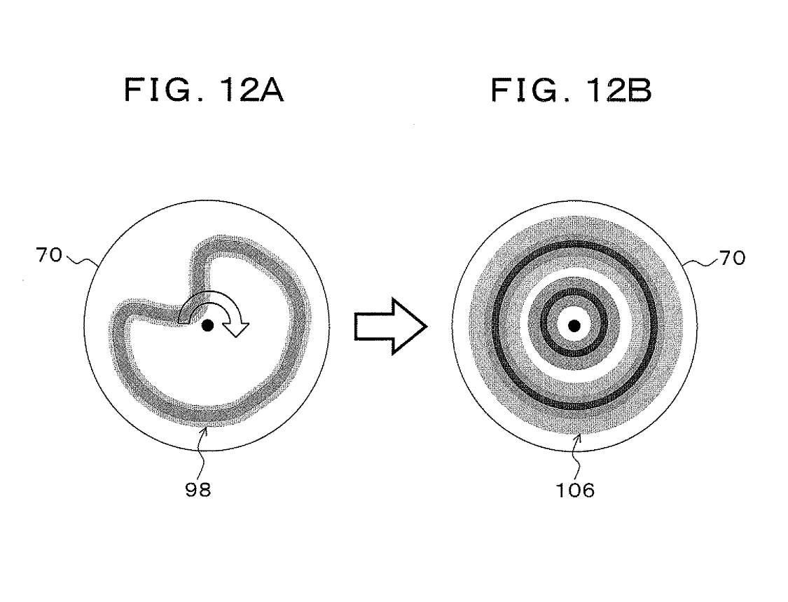

FIGS. 12A and 12B are explanatory diagrams of the process of obtaining the rotational erosion rate distribution by rotating the static erosion rate distribution. in order to uniform the film formation distribution and the erosion distribution, the permanent magnet is rotated in the manner shown in FIG. 12A. Along with that, the static erosion rate distribution 98 calculated based on the erosion center line segment is also rotated, and rotational erosion rate distribution 106 of FIG. 12B is obtained. Note that, since the static erosion rate distribution 98 uniformly erodes the entirety of the target 70 when rotated, the planar shape thereof is not a complete ring, and it has a shape which is partially concave toward the center. Since the plasma in magnetron sputtering apparatus moves while it winds around the magnetic force lines, the erosion rate at each moment when the permanent magnet is rotated can be described by the expression (5). Therefore, the rotational erosion rate distribution can be calculated by subjecting the static erosion rate distribution provided by the expression (5) to integration in accordance with the rotational motion of the permanent magnet. Specifically, when the rotation center of the permanent magnet is a coordinate starting point, the rotational erosion rate Er_rt (x, y) upon rotational motion can be calculated by the below expression.

$$\begin{matrix}\text{[Expression 6]} & \\ Er\_rt ( r ) = \frac{\int Er\_st ( x , y ) r d θ}{2 π r} & ( 6 )\end{matrix}$$

Herein, the static erosion rate Er_st provided by the expression (5) is a value discrete by the lattice points of the two-dimensional meshes serving as, for example, the specified cross section 82 shown in FIG. 10C. In order to calculate the rotational erosion rate distribution Er_rt(r), which takes rotational motion into consideration, by the expression (6), the number of calculation points is deficient and the resolution power of the rotational erosion rate distribution becomes low merely by the static erosion rate distribution obtained for the lattice points of the two-dimensional meshes of the specified cross section; therefore, in order to increase the calculation points, the erosion rates of a plurality of arbitrary points other than the lattice points of the two dimensional meshes have to be calculated. Interpolation of the erosion rate at the arbitrary cell position (x, y) is required. The calculation of the erosion rate at the arbitrary cell position (x, y) is carried out by calculations of two steps.

(1) First-Step Calculation

A cell including the arbitrary position (x, y) is derived by the calculation of the first step. When the coordinate of [Ix][Iy]-th cell is X[Ix],Y[Iy], the cell specifying Ix, Iy satisfying the inequality sign of the below expressions includes the coordinate (x, y) in the two dimensional meshes.

### [Expression 7]

Ix: x>X[Ix]) and (x<X[Ix+1])

Iy: (y>Y[Iy]) and (y<Y[Iy+1]) (7)

(2) Second-Step Calculation

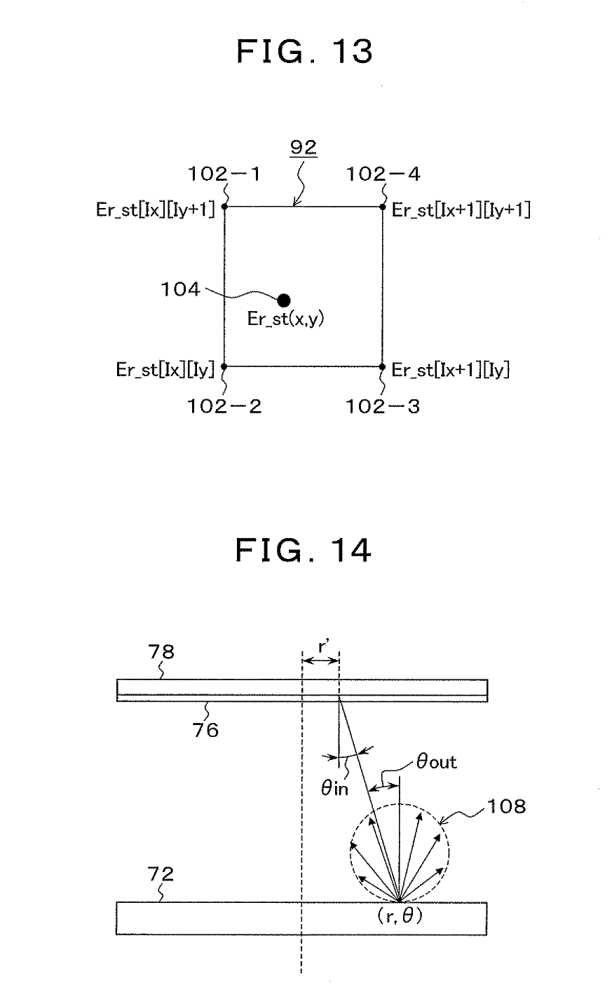

In the calculation of the second step, the erosion rate at the arbitrary position (x, y) is calculated by interpolation. The interpolation uses the interpolation formula of the finite element method. For example, when a cell 92 shown in FIG. 13 specified by the condition of the expressions (7) is taken as an example, with respect to a cell interpolation point 104 at an arbitrary position (x, y) of the cell 92, the erosion rate distribution Er_st calculated by the expression (5) is saved at each of the lattice points 102-1 to 102-4 of the cell lattice points. Therefore, in this case, the erosion rate Er_st (x, y) of the cell interpolation point 104 can be calculated by the below expressions as the interpolation formula of the finite element method.

$$\begin{matrix}\text{[Expression 8]} & \\ Δ x = \frac{x - X [ Ix ]}{X [ Ix + 1 ] - {X [ Ix ]}_{i}} , \\ Δ y = \frac{y - Y [ Iy ]}{Y [ Iy + 1 ] - {Y [ Iy ]}_{i}} , \\ ( 0 \leq Δ x , Δ y \leq 1 ) & ( 8 ) \\ Er\_st ( x , y ) = ( 1 - Δ x ) ( 1 - Δ y ) Er\_st [ Ix ] [ Iy ] + ( Δ x ) ( 1 - Δ y ) Er\_st [ Ix + 1 ] [ Iy ] + ( 1 - Δ x ) ( Δ y ) Er\_st [ Ix ] [ Iy + 1 ] + ( Δ x ) ( Δ y ) Er\_st [ Ix + 1 ] [ Iy + 1 ] & ( 9 )\end{matrix}$$

The expression (8) obtains a relative coordinate (Δx, Δy) of the cell interpolation point 104 in the cell 92 with respect to the lattice points 102-1 to 102-3 using the lattice point 102-1 as a starting point. Then, in the expression (9), by the linear interpolation calculation using the relative coordinate Δx, Δy of the cell interpolation point 104, the erosion rate Er_st (x, y) of the cell interpolation point 104 is obtained from the values of the erosion rates of the lattice points 102-1 to 102-4. When the lattice point in the specified cross section and the static erosion rate distribution of for arbitrary plural positions are calculated in this manner, the rotational erosion rate distribution, which takes the rotational motion into consideration, can be calculated by executing the integration of the expression (6). Next, film formation rate distribution by the film formation rate distribution calculating unit 32 of FIG. 1 will be described with reference to FIG. 14. As shown in FIG. 4, the sputtering particles 75 etched by the collision of the ion atoms generated from the plasma confined on the surface of the target 70 by the magnetic field of the permanent magnet 68 are scattered with scattering angle dependency and adhere the wafer 74, thereby generating film formation 76. The scattering angle dependency of the sputtering particles can be represented by cos [θ]. When the rotational erosion rate distribution can be provided by the expression (6), the film formation rate distribution Sput_rt(r) on the wafer 74 can be calculated by the below expression.

$$\begin{matrix}\text{[Expression 9]} & \\ Sput\_rt ( r ) = {\int }_{0}^{r max\_wf} \frac{{r}^{′} - Er\_rt ( {r}^{′} )}{2 π} ( {\int }_{0}^{2 π} \frac{2 cos ( {θ}_{out} ( {r}^{′} , {θ}^{′} , r ) ) cos ( {θ}_{i n} ( {r}^{′} , {θ}^{′} , r ) )}{{{L}_{{rr}^{′}} ( {r}^{′} , {θ}^{′} , r )}^{2}} d {θ}^{′} ) d {r}^{′} [ µm \text{/} s ] & ( 10 )\end{matrix}$$

Herein, (r′, θ′) represents a coordinate on the target 70. Lrr′ represents a value based on the distance from a position of the thin-film formation surface of the wafer 74 to the target surface position. The expression (10) can be decomposed as below expressions.

$$\begin{matrix}[ Expression 10 ] & \\ Sput\_rt ( {r}^{′} ) = {\int }_{0}^{r max\_ig} \frac{r \cdot Er\_rt ( r )}{2 π} ( {\int }_{0}^{2 π} \frac{2 cos ( {θ}_{out} ) cos ( {θ}_{in}}{{L}_{{rr}^{′}}^{2}} d θ ) d r \\ {L}_{{rr}^{′}}^{2} = {( {r}^{′} - r cos θ )}^{2} + {( r sin θ )}^{2} + {TL}^{2} & ( 11 )\end{matrix}$$

In the expression (12), TL is the distance between the target and the wafer which is a film formation object, and rmax_tg is a target radius. The present invention also provides a recording medium storing the program of the present embodiment. Examples of the recording medium include: portable-type storage media such as CD-ROMs, floppy disks (R), DVD disks, magneto-optical disks, and IC cards; storage apparatuses such as hard disk drives provided inside/outside a computer system; a database which retains programs via lines or another computer system with a database thereof; and online transmission media. The above described embodiment takes the embodiment as a test design system of magnetron sputtering apparatus as an example; however, systems having completely the same contents can be also realized as a simulation method and a simulation system which calculate and predict, in a computer, the erosion rate of a target and film formation rate distribution of a wafer in magnetron sputtering apparatus.

Note that the present invention includes arbitrary modifications that do not impair the object and advantages thereof and is not limited by the numerical values shown in the above described embodiment.

What is claimed is:

1. A design supporting method of magnetron sputtering apparatus which forms a magnetic field in a surface side of a target, which is a film formation material, by a rotating magnet disposed in a back surface side of the target so as to confine plasma and causes ion atoms generated from the plasma to collide with the target at a high speed so as to carry out sputtering and form a thin film on an objective material such as a wafer, the design supporting method of magnetron sputtering includes:
a static magnetic field structure data reading step of reading a static magnetic field structure data generated in a stopped state of the magnet and storing the data in a memory unit;
a cross-section specifying step of specifying, at an arbitrary position of the static magnetic field structure data, a cross section which is parallel with the target surface and in which plasma is generated;
an erosion center line segment calculating step of calculating an erosion center line segment having an endless shape which goes through the center of a region in which a magnetic field vertical to a plane in the specified cross section of the static magnetic field structure data is zero;
a static erosion rate distribution calculating step of calculating static erosion rate distribution in the specified cross section of the static magnetic field structure data based on an erosion rate of the erosion center line segment;
a rotational erosion rate distribution calculating step of calculating rotational erosion rate distribution by integration of the static erosion rate along with rotation of the magnet; and
a film formation rate distribution calculating step of calculating film formation rate distribution on the objective material by using the rotational erosion rate.

2. The design supporting method of magnetron sputtering apparatus according to claim 1, further having a static magnetic field analysis step of generating the static magnetic field structure data, which is read in the static magnetic field structure data reading step, by static magnetic field analysis.

3. The design supporting method of magnetron sputtering apparatus according to claim 1, wherein, in the cross section specifying step, an arbitrary cross section is specified with respect to the static magnetic field structure data based on a specifying operation of a user.

4. The design supporting method of magnetron sputtering apparatus according to claim 1, wherein, in the static magnetic field structure data, objective space is divided into minute cuboidal meshes, a magnetic field (Bx, By, Bz) three-dimensionally calculated based on material property and shapes of the magnet and target present in the objective space is disposed for each coordinate (X[Ix], Y[Iy], Z[Iz]) of a predetermined vertex of the cuboidal mesh.

5. The design supporting method of magnetron sputtering apparatus according to claim 4, wherein, in the erosion center line segment calculating step, when the specified cross section of the static magnetic field structure data cuts the cuboidal mesh, the vertical magnetic field of the cross section position is calculated by interpolation calculations of vertical magnetic fields set at two vertices positioned so as to sandwich the cut surface of the cuboidal mesh in a vertical direction.

6. The design supporting method of magnetron sputtering apparatus according to claim 4, wherein, in the erosion center line segment calculating step,
a line segment in which one side of the vertical magnetic field is a positive magnetic field and the other side is a negative magnetic field is extracted from the line segments between lattice points in the two dimensional meshes constituting the specified cross section of the static magnetic field model; and,
for each extracted line segment, a position at which the vertical magnetic field on the line segment is zero is calculated by linear interpolation calculations of the positive magnetic field and the negative magnetic field, rearrangement is carried out so that the calculated vertical magnetic field zero positions are adjacent to each other, and coordinate data representing an erosion center line is generated.

7. The design supporting method of magnetron sputtering apparatus according to claim 1, wherein, in the erosion center line segment calculating step, a misaligned distance due to centrifugal force caused along rotational motion of plasma particles is calculated and corrected based on curvature of the erosion center line segment.

8. The design supporting method of magnetron sputtering apparatus according to claim 6, wherein, in the static erosion rate distribution calculating step, the static erosion rate distribution is calculated based on an analysis function model such as a Gaussian function.

9. The design supporting method of magnetron sputtering apparatus according to claim 8 wherein, in the static erosion rate distribution calculating step, an erosion rate and distribution width on an erosion center line segment set in advance are read, the distance from a lattice point of the two dimensional meshes constituting the specified cross section of the static magnetic field structure data to the erosion center line segment is calculated, and the static erosion rate of the cell to which the lattice point belongs is calculated based on an specified analysis function such as a Gaussian function wherein the erosion rate, distribution width, and distance are used as calculation parameters.

10. The design supporting method of magnetron sputtering apparatus according to claim 9, in the static erosion rate distribution calculating step, as distances from the lattice point of the two dimensional meshes to the erosion center line segment, the distances between the lattice point and all coordinate points constituting the static erosion center line are calculated,
and a minimum distance among the calculated distances is selected.

11. The design supporting method of magnetron sputtering apparatus according to claim 4, wherein, in the rotational erosion distribution calculating step, the erosion rate at an arbitrary position of the two dimensional mesh in the specified cross section is calculated by an interpolation calculation based on the erosion rates calculated in the static erosion rate calculating step of four lattice points of a cell including the arbitrary position, and the rotational erosion rate distribution is calculated by integration of the erosion rates of the lattice points of the two dimensional meshes and the arbitrary position according to rotation of the magnet.

12. The design supporting method of magnetron sputtering apparatus according to claim 1, wherein, in the film formation rate distribution calculating step, the film formation rate distribution is calculated from the rotational erosion rate distribution and scattering angle dependency.

13. A design supporting system of magnetron sputtering apparatus which forms a magnetic field in a surface side of a target, which is a film formation material, by a rotating magnet disposed in a back surface side of the target so as to confine plasma and causes ion atoms generated from the plasma to collide with the target at a high speed so as to carry out sputtering and form a thin film on an objective material such as a wafer, the design supporting system of magnetron sputtering apparatus having:
a static magnetic field structure data reading unit which reads a static magnetic field structure data generated in a stopped state of the magnet and storing the model in a memory unit;
a cross-section specifying unit which specifies, at an arbitrary position of the static magnetic field structure data, a cross section which is parallel with the target surface and in which plasma is generated;
an erosion center line segment calculating unit which calculates an erosion center line segment having an endless shape which goes through the center of a region in which a magnetic field vertical to a plane in the specified cross section of the static magnetic field structure data is zero;
a static erosion rate distribution calculating unit which calculates static erosion rate distribution in the specified cross section of the static magnetic field structure data based on an erosion rate of the erosion center line segment;
a rotational erosion rate distribution calculating unit which calculates rotational erosion rate distribution by integration of the static erosion rate along with rotation of the magnet; and
a film formation rate distribution calculating unit which calculates film formation rate distribution on the objective material by using the rotational erosion rate.

14. The design supporting system of magnetron sputtering apparatus according to claim 13, wherein the cross section specifying unit specifies an arbitrary cross section with respect to the static magnetic field structure data based on a specifying operation of a user.

15. The design supporting system of magnetron sputtering apparatus according to claim 13, wherein, in the static magnetic field structure data, objective space is divided into minute cuboidal meshes, a magnetic field (Bs, By, Bz) three-dimensionally calculated based on material property and shapes of the magnet and target present in the objective space is disposed for each coordinate (X[Ix], Y[Iy], Z[Iz]) of a predetermined vertex of the cuboidal mesh.

16. The design supporting system of magnetron sputtering apparatus according to claim 15, wherein, when the specified cross section of the static magnetic field structure data cuts the cuboidal mesh, the erosion center line segment calculating unit calculates the vertical magnetic field of the cross section position interpolation calculations of vertical magnetic fields set at two vertices positioned so as to sandwich the cut surface of the cuboidal mesh in a vertical direction.

17. The design supporting system of magnetron sputtering apparatus according to claim 16, wherein the erosion center line segment calculating unit
extracts a line segment, in which one side of the vertical magnetic field is a positive magnetic field and the other side is a negative magnetic field, from the line segments between lattice points in the two-dimensional meshes constituting the specified cross section of the static magnetic field structure data; and,
for each extracted line segment, calculates a position at which the vertical magnetic field on the line segment is zero by linear interpolation calculations of the positive magnetic field and the negative magnetic field, carries out rearrangement so that the calculated vertical magnetic field zero positions are adjacent to each other, and generates coordinate data representing an erosion center line.

18. The design supporting system of magnetron sputtering apparatus according to claim 17, wherein, the static erosion rate distribution calculating unit calculates the static erosion rate distribution based on a Gaussian function model.

19. The design supporting system of magnetron sputtering apparatus according to claim 18, wherein, the static erosion rate distribution calculating unit reads an erosion rate and distribution width on an erosion center line segment set in advance, calculates the distance from a lattice point of the two-dimensional meshes constituting the specified cross section of the static magnetic field structure data to the erosion center line segment, and calculates the static erosion rate of the cell to which the lattice point belongs based on the Gaussian function model wherein the erosion rate, distribution width, and distance are used as calculation parameters.

20. A computer-readable storage medium which stores a program which causes a computer of a design supporting system of magnetron sputtering apparatus which forms a magnetic field in a surface side of a target, which is a film formation material, by a magnet, which is disposed in a back surface side of the target and rotates at a constant speed, so as to confine plasma and causes ion atoms generated from the plasma to collide with the target at a high speed so as to carry out sputtering and form a thin film on an objective material such as a wafer, to execute:
a static magnetic field structure data reading step of reading a static magnetic field structure data generated in a stopped state of the magnet and storing the model in a memory unit;
a cross-section specifying step of specifying, at an arbitrary position of the static magnetic field structure data, a cross section which is parallel with the target surface and in which plasma is generated;
an erosion center line segment calculating step of calculating an erosion center line segment having an endless shape which goes through the center of a region in which a magnetic field vertical to a plane in the specified cross section of the static magnetic field structure data is zero;
a static erosion rate distribution calculating step of calculating static erosion rate distribution in the specified cross section of the static magnetic field structure data based on an erosion rate of the erosion center line segment;
a rotational erosion rate distribution calculating step of calculating rotational erosion rate distribution by integration of the static erosion rate along with rotation of the magnet; and
a film formation rate distribution calculating step of calculating film formation rate distribution on the objective material by using the rotational erosion rate.

21. A simulation method of magnetron sputtering apparatus which forms a magnetic field in a surface side of a target, which is a film formation material, by a rotating magnet disposed in a back surface side of the target so as to confine plasma and causes ion atoms generated from the plasma to collide with the target at a high speed so as to carry out sputtering and form a thin film on an objective material such as a wafer, the simulation method of magnetron sputtering apparatus including:
a static magnetic field structure data reading step of reading a static magnetic field structure data generated in a stopped state of the magnet and storing the model in a memory unit;
a cross-section specifying step of specifying, at an arbitrary position of the static magnetic field structure data, a cross section which is parallel with the target surface and in which plasma is generated;
an erosion center line segment calculating step of calculating an erosion center line segment having an endless shape which goes through the center of a region in which a vertical magnetic field in the specified cross section of the static magnetic field structure data is zero;
a static erosion rate distribution calculating step of calculating static erosion rate distribution in the specified cross section of the static magnetic field structure data based on an erosion rate of the erosion center line segment;
a rotational erosion rate distribution calculating step of calculating rotational erosion rate distribution by integration of the static erosion rate along with rotation of the magnet; and
a film formation rate distribution calculating step of calculating film formation rate distribution on the objective material by using the rotational erosion rate.

22. A simulation system of magnetron sputtering which forms a magnetic field in a surface side of a target, which is a film formation material, by a rotating magnet disposed in a back surface side of the target so as to confine plasma and causes ion atoms generated from the plasma to collide with the target at a high speed so as to carry out sputtering and form a thin film on an objective material such as a wafer, the simulation system of magnetron sputtering having:
a static magnetic field structure data reading unit which reads a static magnetic field structure data generated in a stopped state of the magnet and storing the model in a memory unit;
a cross-section specifying unit which specifies, at an arbitrary position of the static magnetic field structure data, a cross section which is parallel with the target surface and in which plasma is generated;
an erosion center line segment calculating unit which calculates an erosion center line segment having an endless shape which goes through the center of a region in which a magnetic field vertical to a plane in the specified cross section of the static magnetic field structure data is zero;
a static erosion rate distribution calculating unit which calculates static erosion rate distribution in the specified cross section of the static magnetic field structure data based on an erosion rate of the erosion center line segment;
a rotational erosion rate distribution calculating unit which calculates rotational erosion rate distribution by integration of the static erosion rate along with rotation of the magnet; and
a film formation rate distribution calculating unit which calculates film formation rate distribution on the objective material by using the rotational erosion rate.
